(19) United States
(12) Patent Application Publication
(10) Pub. No.: US 2025/0199076 A1
(43) Pub. Date: Jun. 19, 2025

(54) BATTERY STATE ANALYSIS SYSTEM, BATTERY STATE ANALYSIS METHOD, AND NON-TRANSITORY COMPUTER-READABLE RECORDING MEDIUM

(71) Applicant: Panasonic Intellectual Property Management Co., Ltd., Osaka (JP)

(72) Inventors: Takeshi KAWABE, Osaka (JP); Shinya NISHIKAWA, Osaka (JP); Shigeru MATSUDA, Osaka (JP)

(21) Appl. No.: 18/846,860

(22) PCT Filed: Jan. 6, 2023
(86) PCT No.: PCT/JP2023/000193

§ 371 Date: Sep. 13, 2024

(30) Foreign Application Priority Data
Mar. 17, 2022 (JP) 2022-042396

(51) Int. Cl. G01R 31/36; G01R 31/388; G01R 31/396; H01M 10/42

(52) U.S. Cl. CPC G01R 31/3648; G01R 31/388; G01R 31/396; H01M 10/4285

(57) ABSTRACT

A data acquisition unit acquires data for a battery pack including a plurality of cells connected in series or a battery pack including parallel cell blocks connected in series, the parallel cell block being comprised of a plurality of cells connected in parallel. A data processing unit calculates, for each ID, a difference between a voltage value and a representative voltage value that occurs when a maximum voltage value is presented and calculates a statistical value of the difference on a maximum voltage side in a predetermined period. A determination unit determines a cell or a parallel cell block of an ID in which the statistical value on the maximum voltage side deviates from an allowable range on a high voltage side as a recommended target for equalization discharge.

### CROSS-REFERENCE TO RELATED APPLICATIONS

This application is based upon and claims the benefit of priority from the prior Japanese Patent Application No. 2022-042396, filed on Mar. 17, 2022, and the International Patent Application No. PCT/JP2023/000193, filed on Jan. 6, 2023, the entire content of each of which is incorporated herein by reference.

### BACKGROUND

### Field of the Invention

The present disclosure relates to a battery state analysis system, a battery state analysis method, and a battery state analysis program for making an analysis related to an equalization process.

### Description of the Related Art

In a battery pack including a plurality of cells or parallel cell blocks (comprised of a plurality of cells connected in parallel) connected in series, the energy capacity of each cell or parallel cell block may vary. Since the capacity of the entire battery pack strongly depends on the cell or the parallel cell block with the smallest energy capacity, it is required to equalize the energy capacity of the cells or the parallel cell blocks.

It is common that the battery pack mounted on an EV is equipped with a discharging circuit for equalization, but a discharging circuit for equalization is omitted in some inexpensive EV models. In that case, an external charging/discharging apparatus may be connected to cells or parallel cell blocks to perform an equalization process between a plurality of cells or parallel cell blocks at the time of periodic inspection at a repair shop, dealer, etc. There are methods for estimating whether a

variation in energy capacity is occurring by referring to a voltage difference between the maximum voltage and the minimum voltage of a plurality of cells or parallel cell blocks connected in series (see, for example, Patent Literatures 1 and 2).

Patent Literature 1: JP2007-18868

Patent Literature 2: JP2020-128954

When an equalization process is performed using an external charging/discharging apparatus, the cell or the parallel cell block to be discharged, or the cell or the parallel cell block to be charged remains unknown merely by estimating whether a variation is occurring. The work of identifying a cell or a parallel cell block to be discharged or a cell or a parallel cell block to be charged at the base is a cumbersome task and requires long work time.

### SUMMARY OF THE INVENTION

The present disclosure addresses the issue described above, and a purpose thereof is to provide a technology for properly determining a cell or a parallel cell block that should be subject to an equalization process.

A battery state analysis system according to an embodiment of the present disclosure includes: a data acquisition unit that acquires, in a battery pack including a plurality of cells connected in series or a battery pack including parallel cell blocks connected in series, the parallel cell block being comprised of a plurality of cells connected in parallel, an ID of a cell or a parallel cell block presenting a maximum voltage value at each sampling and a voltage and/or an ID of a cell or a parallel cell block presenting a minimum voltage value at each sampling and a voltage value for a predetermined period; a data processing unit that, for each ID, i) calculates a difference between the voltage value and a representative voltage value that occurs when the maximum voltage value is presented and calculates a statistical value of the difference on a maximum voltage side in the predetermined period and/or ii) calculates a difference between the voltage value and the representative value that occurs when the minimum voltage is presented and calculates a statistical value of the difference on a minimum voltage side in the predetermined period; and a determination unit that i) determines a cell or a parallel cell block of an ID in which the statistical value on the maximum voltage side deviates from an allowable range on a high voltage side as a recommended target for equalization discharge and/or ii) determines a cell or a parallel cell block of an ID in which the statistical value on the minimum voltage side deviates from an allowable range on a low voltage side as a recommended target for equalization charge.

Optional combinations of the aforementioned constituting elements, and implementations of the present disclosure in the form of apparatuses, systems, methods, and computer programs are also useful as embodiments of the present disclosure.

Embodiments will now be described, by way of example only, with reference to the accompanying drawings which are meant to be exemplary, not limiting, and wherein like elements are numbered alike in several Figures, in which:

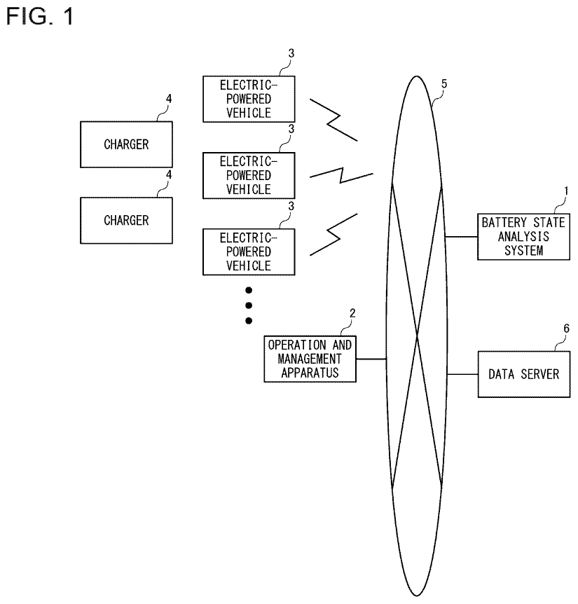

FIG. 1 is a diagram for illustrating a battery state analysis system according to the embodiment.

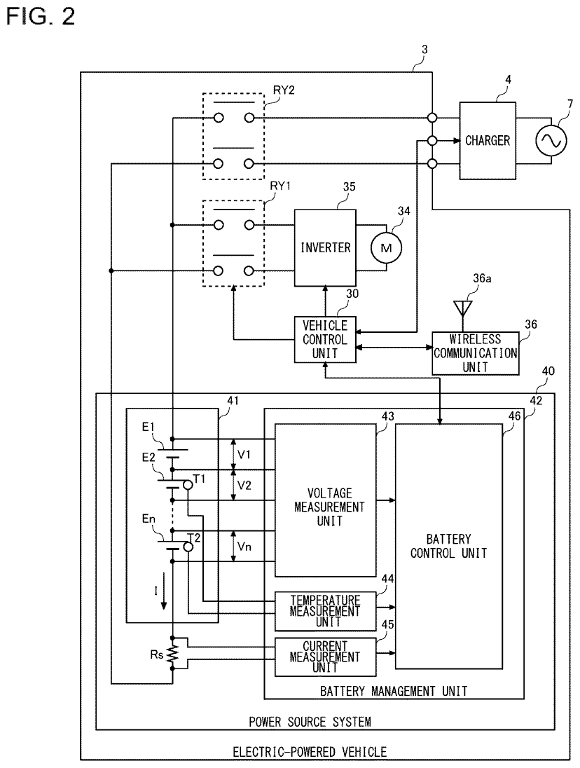

FIG. 2 is a diagram for illustrating a detailed configuration of a power supply system mounted on the electric-powered vehicle.

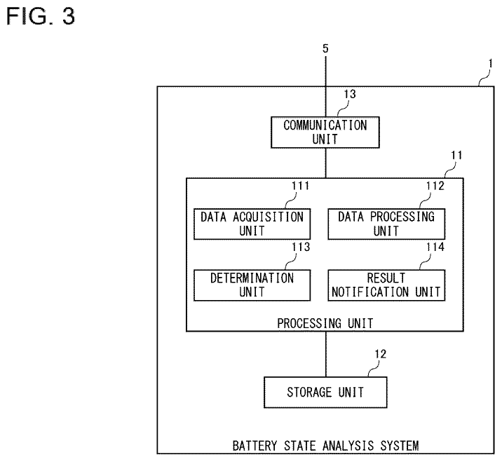

FIG. 3 is a diagram showing an exemplary configuration of the battery state analysis system according to the embodiment.

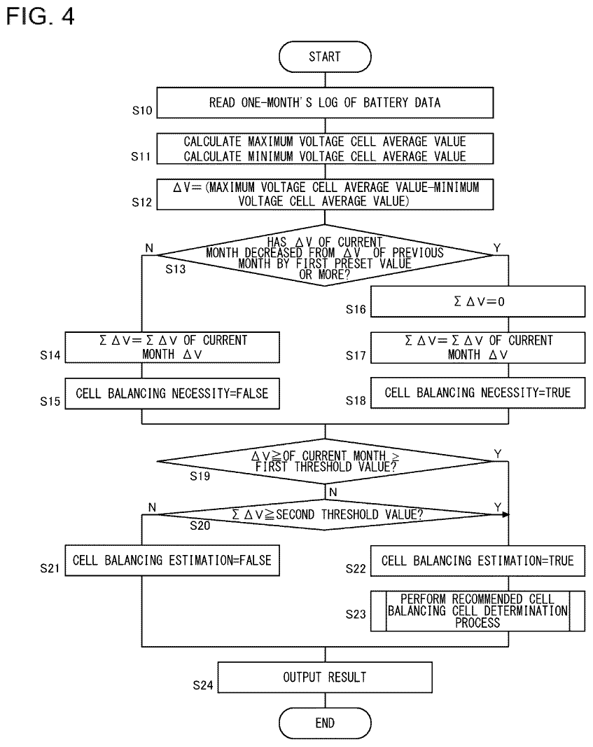

FIG. 4 is a flowchart showing a flow of a determination process related to cell balancing performed by the battery state analysis system according to the embodiment.

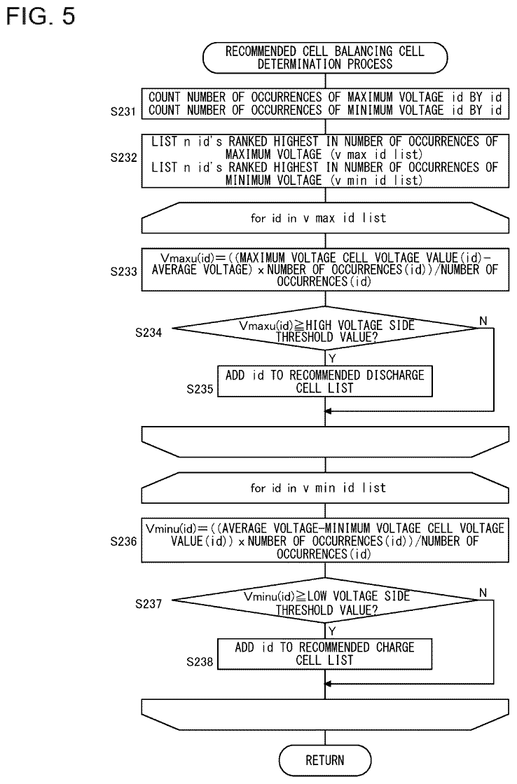

FIG. 5 is a flowchart showing a subroutine in the recommended cell balancing cell determination process of FIG. 4.

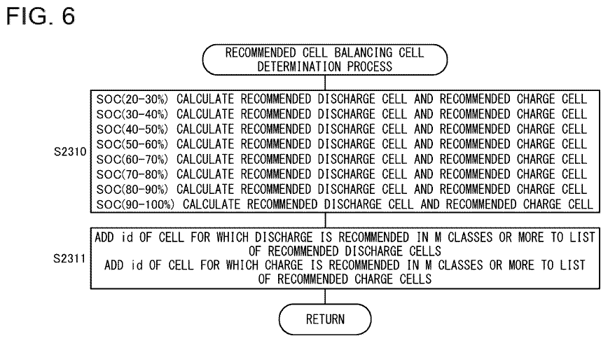

FIG. 6 is a flowchart showing another subroutine in the recommended cell balancing cell determination process of FIG. 4.

### DETAILED DESCRIPTION OF THE INVENTION

The invention will now be described by reference to the preferred embodiments. This does not intend to limit the scope of the present invention, but to exemplify the invention.

FIG. 1 is a diagram for illustrating a battery state analysis system 1 according to the embodiment. The battery state analysis system 1 according to the embodiment is a system used by at least one delivery company. The battery state analysis system 1 may, for example, be built on an in-house server provided in an in-house facility of a service provider that provides a battery state analysis service of a battery pack 41 (see FIG. 2) mounted on an electric-powered vehicle 3 or provided in a data center. Alternatively, the battery state analysis system 1 may be built on a cloud server that is used based on a cloud service contract. Alternatively, the battery state analysis system 1 may be built on a plurality of servers distributed at a plurality of sites (data centers, in-house facilities). The plurality of servers may be any of a combination of a plurality of in-house servers, a combination of a plurality of cloud servers, or a combination of an in-house server and a cloud server.

The network 5 is a general term for communication channels such as the Internet, leased lines, and VPN (Virtual Private Network), and the communication medium and the protocol thereof do not matter. For example, a mobile phone network (cellular network), a wireless LAN, a wired LAN, an optical fiber network, an ADSL network, a CATV network, and the like can be used as the communication medium. For example, TCP (Transmission Control Protocol)/IP (Internet Protocol), UDP (User Datagram Protocol)/IP, Ethernet (registered trademark) and the like can be used as the communication protocol.

The delivery company owns a plurality of electric-powered vehicles 3 and a plurality of chargers 4 and uses the plurality of electric-powered vehicles 3 for delivery business. It should be noted that the electric-powered vehicle 3 can be charged from a charger other than the charger 4 provided at a delivery base. The delivery company owns delivery bases for parking the electric-powered vehicle 3. The operation management terminal apparatus 2 is provided in the delivery base. For example, the operation management terminal apparatus 2 is comprised of a PC. The operation management terminal apparatus 2 is used to manage a plurality of electric-powered vehicle 3 belonging to the delivery base.

The operation management terminal apparatus 2 can access the battery state analysis system 1 via the network 5 and use the service of analyzing the state of the battery pack 41 mounted on the electric-powered vehicle 3. In a state where the electric-powered vehicle 3 is parked at the delivery base, the vehicle control unit 30 (see FIG. 2) of the electric-powered vehicle 3 and the operation management terminal apparatus 2 can exchange data via the network 5 (for example, wireless LAN), a CAN (Controller Area Network) cable, or the like. The vehicle control unit 30 and the operation management terminal apparatus 2 may be configured to exchange data via the network 5 even while the electric-powered vehicle 3 is traveling.

The data server 6 acquires and stores traveling data from the operation management terminal apparatus 2 or the electric-powered vehicle 3. The data server 6 may be an in-house server provided in an in-house facility of a delivery company or a battery state analysis service provider or in a data center. The data server 6 may be a cloud server used by the delivery company or the battery state analysis service provider. Further, each delivery company and battery state analysis service provider may have the data server 6.

FIG. 2 is a diagram for illustrating a detailed configuration of a power supply system 40 mounted on the electric-powered vehicle 3. The power supply system 40 is connected to a motor 34 via a first relay RY1 and an inverter 35. The inverter 35 converts a DC power supplied from the power supply system 40 into an AC power and supplies it to the motor 34 during power running. During regeneration, the inverter 35 converts the AC power supplied from the motor 34 into a DC power and supplies it to the power supply system 40. The motor 34 is a three-phase AC motor and rotates according to the AC power supplied from the inverter 35 during power running. During regeneration, the motor 34 converts the rotational energy caused by deceleration into an AC power and supplies it to the inverter 35.

The vehicle control unit 30 is a vehicle ECU (Electronic Control Unit) that controls the entire electric-powered vehicle 3 and may be, for example, comprised of an integrated VCM (Vehicle Control Module). A wireless communication unit 36 has a modem and performs a wireless signal process for wireless connection to the network 5 via an antenna 36a. Examples of a wireless communication network to which the electric-powered vehicle 3 can be wirelessly connected include a mobile phone network (cellular network), a wireless LAN, V2I (Vehicle-to-Infrastructure), V2V (Vehicle-to-Vehicle), ETC system (Electronic Toll Collection System), and DSRC (Dedicated Short Range Communications).

The first relay RY1 is a contactor inserted between the wirings connecting the power supply system 40 and the inverter 35. The vehicle control unit 30 controls the first relay RY1 to be on (closed state) while the vehicle is running to electrically connect the power supply system 40 and the power system of the electric-powered vehicle 3. While the vehicle is not running, the vehicle control unit 30 controls the first relay RY1 to be off (open state) in principle and electrically cuts off the power supply system 40 and the power system of the electric-powered vehicle 3 from each other. Instead of a relay, a different type of switch such as a semiconductor switch may be used.

The electric-powered vehicle 3 is adapted to charge the battery pack 41 in the power supply system 40 from outside by being connected to the charger 4. The charger 4 is connected to a commercial power system 7 and charges the battery pack 41 in the electric-powered vehicle 3. In the electric-powered vehicle 3, a second relay RY2 is inserted between the wirings connecting the power supply system 40 and the charger 4. Instead of a relay, a different type of switch such as a semiconductor switch may be used. A battery management unit 42 controls the second relay RY2 to be on via the vehicle control unit 30 or directly before charging is started and controls the second relay RY2 to be off after charging is completed.

In general, a battery is charged with AC in the case of normal charging and is charged with DC in the case of fast charging. In the case of charging the battery with AC (for example, single-phase 100/200 V), the AC power is converted into a DC power by an AC/DC converter (not shown) inserted between the second relay RY2 and the battery pack 41. In the case of charging the battery with DC, the charger 4 generates the DC power by rectifying the AC power supplied from the commercial power system 7 in full wave rectification and smoothing the power with a filter.

Examples of fast charging standards that can be used include CHAdeMO (registered trademark), ChaoJi, GB/T, Combo (Combined Charging System). CHAdeMO2.0 stipulates that the maximum output (specification) is 1000V×400A=400kW. CHAdeMO3.0 stipulates that the maximum output (specification) is 1500V×600A=900kW. ChaoJi stipulates that the maximum output (specification) is 1500V×600A=900kW. GB/T stipulates that the maximum output (specification) is 750V×250A=185kW. Combo stipulates that the maximum output (specification) is 900V×400A=350KW. CHAdeMO, ChaoJi, and GB/T use CAN as the communication method. Combo uses PLC (Power Line Communication) as the communication method.

In addition to power lines, communication lines are also included in the charging cable in which the CAN scheme is employed. When the electric-powered vehicle 3 and the charger 4 are connected by the charging cable, the vehicle control unit 30 establishes a communication channel with the control unit in the charger 4. In the charging cable in which the PLC scheme is employed, a communication signal is superimposed and transmitted on the power line.

The vehicle control unit 30 establishes a communication channel with the battery management unit 42 via a vehicle-mounted network (for example, CAN or LIN (Local Interconnect Network)). When the communication standard between the vehicle control unit 30 and the control unit in the charger 4 and the communication standard between the vehicle control unit 30 and the battery management unit 42 are different, the vehicle control unit 30 performs a gateway function.

The power supply system 40 mounted on the electric-powered vehicle 3 includes the battery pack 41 and the battery management unit 42. The battery pack 41 includes a plurality of cells E1-En or a plurality of parallel cell blocks. A lithium ion battery cell, a nickel hydride battery cell, a lead battery cell or the like can be used as the cell. Hereinafter, an example of using a lithium ion battery cell (nominal voltage: 3.6-3.7 V) is assumed in this specification. The number of cells E1-En or parallel cell blocks connected in series is determined according to the drive voltage of the motor 34.

A shunt resistor Rs is connected in series with the plurality of cells E1-En or the plurality of parallel cell blocks. The shunt resistor Rs functions as a current-sensing element. A Hall element may be used instead of the shunt resistor Rs. A plurality of temperature sensors T1, T2 for detecting the temperature of the plurality of cells E1-En or the plurality of parallel cell blocks are provided in the battery pack 41. For example, a thermistor can be used as the temperature sensors T1, T2. For example, one temperature sensor may be provided for 6-8 cells or parallel cell blocks.

The battery management unit 42 includes a voltage measurement unit 43, a temperature measurement unit 44, a current measurement unit 45, and a battery control unit 46. The nodes of the plurality of cells E1-En or the plurality of parallel cell blocks connected in series and the voltage measurement unit 43 are connected by a plurality of voltage lines. The voltage measurement unit 43 measures the voltage of each cell E1-En or each parallel cell block by measuring the voltage between two adjacent voltage lines respectively. The voltage measurement unit 43 transmits the voltage of each cell E1-En or each parallel cell block thus measured to the battery control unit 46.

Since the voltage measurement unit 43 is at a higher voltage than the battery control unit 46, the voltage measurement unit 43 and the battery control unit 46 are connected by a communication line in an electrically insulated state. The voltage measurement unit 43 can be comprised of an ASIC (Application Specific Integrated Circuit) or a general-purpose analog front-end IC. The voltage measurement unit 43 includes a multiplexer and an A/D converter. The multiplexer successively outputs the voltage between two adjacent voltage lines to the A/D converter from top to bottom. The A/D converter converts the analog voltage input from the multiplexer into a digital value.

The temperature measurement unit 44 includes a voltage divider resistor and an A/D converter. The A/D converter converts a plurality of analog voltages divided by the plurality of temperature sensors T1, T2 and the plurality of voltage divider resistors into digital values successively and outputs them to the battery control unit 46. The battery control unit 46 measures the temperature at a plurality of observation points in the battery pack 41 based on the plurality of digital values.

The current measurement unit 45 includes a differential amplifier and an A/D converter. The differential amplifier amplifies the voltage across the shunt resistor Rs and outputs the amplified voltage to the A/D converter. The A/D converter converts the analog voltage input from the differential amplifier into a digital value and outputs it to the battery control unit 46. The battery control unit 46 measures a current I flowing through the plurality of cells E1-En or the plurality of parallel cell blocks based on the digital value.

In the case an A/D converter is mounted in the battery control unit 46 and an analog input port is provided in the battery control unit 46, the temperature measurement unit 44 and the current measurement unit 45 may output an analog voltage to the battery control unit 46, and the A/D converter in the battery control unit 46 may convert the analog voltage into a digital value.

The battery control unit 46 manages the state of the plurality of cells E1-En or the plurality of parallel cell blocks based on the voltage, temperature, and current of the plurality of cells E1-En or the plurality of parallel cell blocks measured by the voltage measurement unit 43, the temperature measurement unit 44, and the current measurement unit 45. When an overvoltage, undervoltage, overcurrent, or temperature abnormality occurs in at least one of the plurality of cells E1-En or the plurality of parallel cell blocks, the battery control unit 46 turns off the second relay RY2 or the protection relay (not shown) in the battery pack 41 to protect the cell or the parallel cell block.

The battery control unit 46 can be comprised of a microcontroller and a non-volatile memory (e.g., EEPROM (Electrically Erasable Programmable Read-Only Memory), flash memory). The battery control unit 46 estimates the SOC (State Of Charge) of each of the plurality of cells E1-En or the plurality of parallel cell blocks.

The battery control unit 46 estimates SOC by combining the OCV (Open Circuit Voltage) method and the current integration method. The OCV method is a method of estimating SOC based on the OCV of each cell measured by the voltage measurement unit 43 and the SOC-OCV curve of the cell. The SOC-OCV curve of the cell is created in advance based on a characteristic test by the battery manufacturer and is registered in the internal memory of the microcontroller at the time of shipment.

The current accumulation method is a method of estimating SOC based on the OCV at the start of charging or discharging of each cell and the integrated value of the current measured by the current measurement unit 45. In the current accumulation method, the measurement error of the current measurement unit 45 accumulates as the charging/discharging time increases. On the other hand, the OCV method is affected by the measurement error of the voltage measurement unit 43 and the error caused by the polarization voltage. It is therefore preferable to use a weighted average of the SOC estimated by the current accumulation method and the SOC estimated by the OCV method.

The battery control unit 46 periodically (for example, every 10 seconds) samples battery data including voltage, current, temperature, and SOC of each cell E1-En or each parallel cell block and transmits the data to the vehicle control unit 30 via the vehicle-mounted network. In the case the number of cells E1-En or parallel cell blocks connected in series (corresponding to number of channels of voltage measurement) is large, the battery control unit 46 may transmit, as voltage data, only the maximum voltage and the minimum voltage of the plurality of cells E1-En or parallel cell blocks to the vehicle control unit 30. In this case, the battery control unit 46 includes the ID of the cell or the parallel cell block presenting the maximum voltage and the ID of the cell or the parallel cell block presenting the minimum voltage into the battery data. In this embodiment, the channel number is used as the ID of the cell or the parallel cell block.

The battery control unit 46 may transmit the terminal voltage of the entire battery pack 41 to the vehicle control unit 30 in addition to the maximum voltage and the minimum voltage. The terminal voltage of the battery pack 41 may be determined by adding up the voltages of the plurality of cells E1-En or parallel cell blocks or separately providing a voltage divider resistor for measuring the terminal voltage of the battery pack 41.

Further, the battery control unit 46 may estimate the SOC of the entire battery pack 41 based on the SOC of the plurality of cells E1-En or parallel cell blocks and transmit only the SOC of the entire battery pack 41 to the vehicle control unit 30 as the SOC data.

The vehicle control unit 30 can transmit battery data to the data server 6 in real time using the wireless communication unit 36 while the electric-powered vehicle 3 is running. Alternatively, the vehicle control unit 30 may store the battery data for the electric-powered vehicle 3 in the internal memory and collectively transmit the battery data stored in the memory at a predetermined point of time. For example, the vehicle control unit 30 may be started periodically while the electric-powered vehicle 3 is being parked and may use the wireless communication unit 36 to collectively transmit the battery data stored in the memory to the data server 6.

Alternatively, the vehicle control unit 30 may collectively transmits the battery data stored in the memory to the operation management terminal apparatus 2 at the end of the day's business. The operation management terminal apparatus 2 transmits the battery data for the plurality of electric-powered vehicles 3 to the data server 6 according to a predetermined timing schedule. Alternatively, the vehicle control unit 30 may collectively transmit the battery data stored in the memory to the charger 4 having a network communication function via the charging cable when the battery is charged by the charger 4. The charger 4 having a network communication function transmits the received battery data to the data server 6. This example is useful for the electric-powered vehicle 3 not equipped with a wireless communication function.

FIG. 3 is a diagram showing an exemplary configuration of the battery state analysis system 1 according to the embodiment. The battery state analysis system 1 includes a processing unit 11, a storage unit 12, and a communication unit 13. The communication unit 13 is a communication interface (for example, NIC: Network Interface Card) for connecting to the network 5 by wire or wirelessly.

The processing unit 11 includes a data acquisition unit 111, a data processing unit 112, a determination unit 113, and a result notification unit 114. The function of the processing unit 11 can be realized by cooperation between hardware resources and software resources or by hardware resources alone. Hardware resources such as CPU, ROM, RAM, GPU (Graphics Processing Unit), ASIC (Application Specific Integrated Circuit), FPGA (Field Programmable Gate Array), and other LSIs can be used. Programs such as operating systems and applications can be used as software resources. The storage unit 12 is inclusive of a non-volatile recording medium such as a HDD and an SSD and stores various data.

The data acquisition unit 111 acquires, from the data server 6, battery data for a particular battery packs 41 mounted on the electric-powered vehicle 3 in a predetermined period (in this embodiment, one month). The battery data at least includes the ID and the voltage value of the cell or the parallel cell block presenting the maximum voltage value at each sampling, and the ID and the voltage value of the cell or the parallel cell block presenting the minimum voltage at each sampling.

The data processing unit 112 and the determination unit 113 estimate whether an equalization process should be performed and estimate the cell or the parallel cell block that should be subject to an equalization process, by referring to log data that includes the ID and the voltage value of the cell or the parallel cell block presenting the maximum voltage value and the ID and the voltage value of the cell or the parallel cell block presenting the minimum voltage. A detailed description will be given below.

For each ID, the data processing unit 112 calculates a difference between the voltage value and a representative voltage value that occurs when the maximum voltage value is presented and calculates a statistical value of the difference on the maximum voltage side in a predetermined period. For each ID, the data processing unit 112 calculates a difference between the voltage value and the representative voltage value that occurs when the minimum voltage value is presented and calculates a statistical value of the difference on the minimum voltage side in a predetermined period. For example, the data processing unit 112 can use, as the representative voltage value, an average voltage value sampled at the same point of time as the maximum voltage value or the minimum voltage value. The median value may be used instead of the average voltage value.

When the voltage values of the cells or the parallel cell blocks sampled at the same point of time in all channels are acquired, the data processing unit 112 may average the voltage values of the cells or the parallel cell blocks in all channels to generate an average voltage value. When the terminal voltage value of the battery pack 41 sampled at the same point of time is acquired, the data processing unit 112 may generate an average voltage value by dividing the sample voltage value of the battery pack 41 by the number of cells or parallel cell blocks connected in series. When only the maximum voltage value and the minimum voltage value sampled at the same point of time are acquired, the data processing unit 112 may average the maximum voltage value and the minimum voltage value to generate an average voltage value.

The data processing unit 112 may, as the representative voltage value, use an average voltage value derived from averaging all voltage values of all cells or parallel cell blocks included in a predetermined period. The median value or mode value of all voltage values of all cells or parallel cell blocks included in a predetermined period may be used.

The statistical value of the difference between the maximum voltage value and the representative voltage value on the maximum voltage side in a predetermined period may be an average value, a median value, or a mode value of the difference in the predetermined period. Similarly, the statistical value of the difference between the minimum voltage value and the representative voltage value on the minimum voltage side in a predetermined period may be an average value, a median value, or a mode value of the difference in the predetermined period.

The determination unit 113 determines the cell or the parallel cell block of the ID in which the statistical value on the maximum voltage side deviates from the allowable range on the high voltage side as a recommended target for equalization discharge. Similarly, the determination unit 113 determines the cell or the parallel cell block of the ID in which the statistical value on the minimum voltage side deviates from the allowable range on the low voltage side as a recommended target for equalization charge.

In order to reduce the amount of calculation, the data processing unit 112 may calculate the statistical value on the maximum voltage side only for the IDs of a predetermined number of (e.g., five) cells or parallel cell blocks ranked highest in the frequency of presenting the maximum voltage value in a predetermined period, and the determination unit 113 may determine whether the statistical value on the maximum voltage side deviates from the allowable range on the high voltage side only for the IDs of the predetermined number of cells or parallel cell blocks ranked highest. Similarly, the data processing unit 112 may calculate the statistical value on the minimum voltage side only for the IDs of a predetermined number of (e.g., five) cells or parallel cell blocks ranked highest in the frequency of presenting the minimum voltage value in a predetermined period, and the determination unit 113 may determine whether the statistical value on the minimum voltage side deviates from the allowable range on the low voltage side only for the IDs of the predetermined number of cells or parallel cell blocks ranked highest.

In order to reduce the amount of calculation, it may be determined whether an equalization process is necessary prior to determining the cell or the parallel cell block subject to equalization discharge and equalization charge described above. Only when it is determined that an equalization process is necessary, the statistical value on the maximum voltage side and the statistical value on the minimum voltage side in a predetermined time may be calculated, and control may proceed to a process of determining cells or parallel cell blocks subject to equalization discharge and equalization charge (hereinafter, referred to as a recommended equalization cell determination process).

The data processing unit 112 calculates the maximum voltage average value by averaging the maximum voltage values sampled in a predetermined period. Similarly, the data processing unit 112 calculates the minimum voltage average value by averaging the minimum voltage values sampled in a predetermined period. In the calculation of the maximum voltage average value and the minimum voltage average value, the maximum voltage value and the minimum voltage value of the entire cells or parallel cell blocks are used without dividing the cells or parallel cell blocks according to ID. The data processing unit 112 calculates an average differential voltage value by subtracting the minimum voltage average value from the maximum voltage average value. In consideration of a measurement error (offset), the average differential voltage value may be set to 0 when the value becomes equal to or smaller than a preset voltage error. In the case the maximum voltage average value is 4.20 V and the minimum voltage average value is 4.16 V, for example, the average differential voltage value will be 0 V instead of 0.04 V given that the preset voltage error is set to 0.06 V.

Further, the data processing unit 112 calculates a cumulative average differential voltage value by accumulating average differential voltage values in the respective predetermined periods. The data processing unit 112 adds the currently calculated average differential voltage value to the cumulative average differential voltage value each time the average differential voltage value in a predetermined period is calculated. In this embodiment, the data processing unit 112 monthly calculates the average differential voltage value for one month and adds the calculated average differential voltage value to the cumulative average differential voltage value.

When the currently calculated average differential voltage in the predetermined period is smaller by the first preset value or more than the previously calculated average differential voltage in the predetermined period, the data processing unit 112 resets the cumulative average differential voltage value. When this condition is satisfied, it can be presumed that the equalization process was performed between the time of previous calculation and the time of current calculation. That is, it can be presumed that the voltage variation between a plurality of cells or parallel cell blocks has been reduced by the equalization process. After resetting the cumulative average differential voltage value, the data processing unit 112 adds the currently calculated average differential voltage in the predetermined period to the cumulative average differential voltage value. The user may be notified that the battery state has been improved, and it may be determined whether to reset the cumulative average differential voltage value based on the user's answer. Alternatively, the user may simply be notified that the battery state has been improved after the cumulative average differential voltage value is reset.

When the currently calculated average differential voltage in the predetermined period is not smaller by the first preset value or more than the previously calculated average differential voltage in the predetermined period, the data processing unit 112 does not reset the cumulative average differential voltage value and adds the currently calculated average differential voltage value to the cumulative average differential voltage value. In this case, it can be presumed that an equalization process has not been performed between the time of previous calculation and the time of current calculation.

When the currently calculated average difference voltage in the predetermined period is smaller than the first threshold value, the data processing unit 112 skips the recommended equalization cell determination process. When this condition is satisfied, it is determined that the need to perform an equalization process is low, and the recommended equalization cell determination process is skipped to reduce the amount of computation.

Further, the data processing unit 112 may skip the recommended equalization cell determination process when the currently calculated average difference voltage in the predetermined period is smaller than the first threshold value and the cumulative average differential voltage value is smaller than the second threshold value. In this example, it is possible to determine whether an equalization process should be performed in consideration of not only the voltage variation between a plurality of cells or parallel cell blocks in the most recent predetermined period, but also the duration of voltage variation. In this example, control proceeds to the recommended equalization cell determination process when it is presumed that a voltage variation is continuing for a long time, even if the currently calculated average differential voltage in the predetermined period is smaller than the first threshold value.

Voltage values having low reliability may be excluded to increase the accuracy of data processing. The data acquisition unit 111 acquires the SOC of the battery pack 41 at each sampling for a predetermined period. Further, the data acquisition unit 111 may acquire the SOC at each sampling for a predetermined period by calculating the SOC at each sampling based on the current value, voltage value, etc. of the battery pack 41 at each sampling. That is, the SOC may be estimated on the side of the battery state analysis system 1 instead of on the side of the electric-powered vehicle 3. The data processing unit 112 excludes from data processing voltage values sampled when the SOC of the battery pack 41 is smaller than the second preset value (for example, 20%). In general, the reliability of measured voltages will be low in a low SOC zone. Further, the data processing unit 112 may exclude from data processing voltage values sampled when the SOC of the battery pack 41 is equal to or more than the third preset value (for example, 90%). Depending on the type of battery, some measured values are prone to deviation in a high SOC zone.

Further, the data acquisition unit 111 acquires the current value of the battery pack 41 at each sampling for a predetermined period. The data processing unit 112 excludes from data processing voltage values sampled when the current value of the battery pack is equal to or larger than the fourth preset value (set to a positive value) or smaller than the fifth preset value (set to a negative value). The measured voltage during a period when a large current is flowing due to quick charging or sudden acceleration will deviate greatly from OCV, and the reliability of the measured voltage will be low. It should be noted that the same preset value may be used at the time of charging and at the time of discharging, or different preset values may be used. A filter that excludes voltage values in a low SOC zone, a filter that excludes voltage values in a high SOC zone, a filter that excludes voltage values during a period when a large positive current is flowing, and a filter that excludes voltage values during a period when a large negative current is flowing may be performed altogether, or at least one of them may be performed.

For the purpose of improving the accuracy of the recommended equalization cell determination process, voltage variation may be evaluated for each SOC zone, and a cell or a parallel cell block for which discharging is recommended and a cell or a parallel cell block for which charging is recommended may be determined ultimately based on the overall evaluation.

The data processing unit 112 calculates the statistical value on the maximum voltage side and the statistical value on the minimum voltage side for each SOC class derived from dividing SOC at predetermined intervals (e.g., 10% intervals). The determination unit 113 determines, as a recommended target for equalization discharge, a cell or a parallel cell block of an ID in which the statistical value on the maximum voltage side deviates from the allowable range on the high voltage side in a predetermined number of (for example, 3-7) SOC classes or more. Similarly, the determination unit 113 determines, as a recommended target for equalization charge, a cell or a parallel cell block of an ID in which the statistical value on the minimum voltage side deviates from the allowable range on the low voltage side in a predetermined number of SOC classes or more.

The result notification unit 114 transmits, to the data server 6, a determination result including the necessity of an equalization process and each ID of a cell or a parallel cell block for which equalization discharge or equalization charging is recommended in the case an equalization process is required.

The person in charge of battery management at the delivery company can access the data server 6 via the network 5 rom the operation management terminal apparatus 2 to refer to or download the determination result related to the equalization process of the battery pack 41 mounted on each electric-powered vehicle 3. The person in charge of battery management at the delivery company delivers the judgment result related to the equalization process in each battery pack 41 to the operator at the time of periodic inspection at a repair shop, dealer, etc. Referring to the determination result, the operator performs an operation of discharging each cell or parallel cell block for which discharging is recommended and an operation of charging each cell or parallel cell block for which charging is recommended.

FIG. 4 is a flowchart showing a flow of a determination process related to cell balancing performed by the battery state analysis system 1 according to the embodiment. The data acquisition unit 111 reads one-month's log data for a particular battery pack 41 from the data server 6 (S10). The data processing unit 112 calculates the maximum voltage cell average voltage value by averaging the maximum voltage values of the cells or the parallel cell blocks sampled for one month. Similarly, the data processing unit 112 calculates the minimum voltage cell average voltage value by averaging the minimum voltage values of the cells or the parallel cell blocks sampled for one month (S11). The data processing unit 112 calculates the cell average differential voltage value ΔV by subtracting the minimum voltage cell average voltage value from the maximum voltage cell average voltage value (S12).

The data processing unit 112 compares the cell average differential voltage value ΔV of the previous month and the cell average differential voltage value ΔV of the current month (S13). When the cell average differential voltage value ΔV of the current month has not decreased by the first preset value or more from the cell average differential voltage value ΔV of the previous month (N in S13), the data processing unit 112 adds the cell average differential voltage value ΔV of the current month to the cumulative cell average differential voltage value ΣΔV (S14). The data processing unit 112 sets FALSE in the cell balancing estimation flag (S15).

When the cell average differential voltage value ΔV of the current month has decreased by the first preset value or more from the cell average differential voltage value ΔV of the previous month (Y in S13), the data processing unit 112 resets the cumulative cell average differential voltage value ΣΔV (S16). The data processing unit 112 adds the cell average differential voltage value ΔV of the current month to the cumulative cell average differential voltage value ΣΔV (S17). The data processing unit 112 sets TRUE in the cell balancing estimation flag (S18).

The data processing unit 112 compares the cell average differential voltage value ΔV of the current month with the first threshold value with (S19). When the cell average differential voltage value ΔV of the current month is equal to or larger than the first threshold value (Y in S19), the data processing unit 112 sets TRUE in the cell balancing necessity flag (S22). The data processing unit 112 and the determination unit 113 perform a recommended cell balancing cell determination process (S23).

When the cell average differential voltage value ΔV of the current month is smaller than the first threshold value (N in $19), the data processing unit 112 compares the cumulative cell average differential voltage value ΣΔV with the second threshold value (S20). When the cumulative cell average differential voltage value ΣΔV is equal to or larger than the second threshold value (Y in S20), the data processing unit 112 sets TRUE in the cell balancing necessity flag (S22). The data processing unit 112 and the determination unit 113 perform a recommended cell balancing cell determination process (S23). When the cumulative cell average differential voltage value ΣΔV is smaller than the second threshold value (N in S20), the data processing unit 112 sets FALSE in the cell balancing necessity flag (S21).

The result notification unit 114 transmits, to the data server 6, a determination result including the cell balancing necessity flag and each ID of the cell or the parallel cell block for which discharging or charging is recommended in the case the cell balancing necessity flag is TRUE (S24).

FIG. 5 is a flowchart showing a subroutine in the recommended cell balancing cell determination process of FIG. 4. The data processing unit 112 counts the number of occurrences of the maximum voltage value for one month ID by ID and counts the number of occurrences of the minimum voltage value for one month ID by ID (S231). The data processing unit 112 lists a total of n (e.g., n=5) id's ranked highest in the number of occurrences of the maximum voltage (v max id list). Similarly, the data processing unit 112 lists a total of n (e.g., n=5) id's ranked highest in the number of occurrences of the minimum voltage (S232) (v min id list). The data processing unit 112 performs the

following steps S233-S235 for each id included in the maximum voltage list (v max id list). The data processing unit 112 calculates the following (expression 1) to calculate the maximum voltage cell average voltage value ΔVmaxu(id) id by id (S233). ΔVmaxu(id)=((maximum voltage cell voltage value (id)−average voltage value)×number of occurrences(id))/number of occurrences(id) . . . (expression 1)

The data processing unit 112 compares the maximum voltage cell average voltage value ΔVmaxu(id) and a high voltage side threshold value (S234). When the maximum voltage cell average voltage value ΔVmaxu(id) is equal to or larger than the high voltage side threshold value (Y in S234), the data processing unit 112 adds the id to the list of recommended discharge cells or parallel cell blocks (S235). When the maximum voltage cell average voltage value ΔVmaxu(id) is smaller than the high voltage side threshold value (N in S234), step S235 is skipped.

The data processing unit 112 performs the following steps S236-S238 for each id included in the minimum voltage list (v min id list). The data processing unit 112 calculates the following (expression 2) to calculate the minimum voltage cell average voltage value ΔVminu(id) id by id (S236). ΔVminu(id)=((average voltage value-minimum voltage cell voltage value (id))×number of occurrences(id))/number of occurrences(id) . . . (expression 2)

The data processing unit 112 compares the minimum voltage cell average voltage value ΔVminu(id) and a low voltage side threshold value (S237). When the minimum voltage cell average voltage value ΔVminu(id) is equal to or larger than the low voltage side threshold value (Y in S237), the data processing unit 112 adds the id to the list of recommended charge cells or parallel cell blocks (S238).

When the minimum voltage cell average voltage value ΔVminu(id) is smaller than the low voltage side threshold value (N in S237), step S238 is skipped.

When there are no ids to be added to the list of recommended discharge cells or parallel cell blocks, and there are no id's to be added to the list of recommended charge cells or parallel cell blocks, the data processing unit 112 sets FALSE in the cell balancing necessity flag.

FIG. 6 is a flowchart showing another subroutine in the recommended cell balancing cell determination process of FIG. 4. In this example, voltage values sampled when the SOC of the battery pack 41 is smaller than 20% are excluded from data processing. The data processing unit 112 calculates a recommended discharge cell or parallel cell block and a recommended charge cell or parallel cell block in eight SOC classes (20-30%, 30-40%, 40-50%, 50-60%, 60-70%, 70-80%, 80-90%, 90-100%) derived from dividing the SOC at 10% intervals (S2310).

The data processing unit 112 adds the id of the cell or the parallel cell block for which discharging is recommended in M (e.g., M=6) classes or more to the ultimate list of recommended discharge cells or parallel cell blocks. Similarly, the data processing unit 112 adds the id of the cell or the parallel cell block for which charging is recommended in M (e.g., M=6) classes or more to the ultimate list of recommended charge cells or parallel cell blocks (S2311).

When there are no ids to be added to the ultimate list of recommended discharge cells or parallel cell blocks, and there are no id's to be added to the ultimate list of recommended charge cells or parallel cell blocks, the data processing unit 112 sets FALSE in the cell balancing necessity flag.

Each of the first preset value, the second preset

value, the third preset value, the fourth preset value, the fifth preset value, the first threshold value, the second threshold value, the high voltage side threshold value, and the low voltage side threshold value is set to a value determined by the designer to be most appropriate, based on at least one of an experimental result, a simulation result, or the designer's knowledge.

As described above, the embodiment makes it possible to properly determine whether cell balancing is necessary and determine a cell or a parallel cell block that should be subject to cell balancing and discharged or charged accordingly. Since the cell or the parallel cell block that should be discharged or charged is determined based on the statistical value of the maximum voltage value or the statistical value of the minimum voltage value, impact from noise is reduced and highly accurate determination is made possible. Since the cell or the parallel cell block that should be discharged or charged is identified in advance at the time of inspection or repair of the electric-powered vehicle 3, cell balancing work using an external charge/discharge apparatus can be efficiently carried out.

Given above is a description of the present disclosure based on the embodiment. The embodiment is intended to be illustrative only and it will be understood by those skilled in the art that various modifications to combinations of constituting elements and processes are possible and that such modifications are also within the scope of the present disclosure.

In the above-described embodiment, an example of determining both a recommended discharge cell or parallel cell block and a recommended charge cell or parallel cell block has been described. It will be noted that only one of them may be determined. For example, only the recommended discharge cell or parallel cell block is determined, and the recommended discharge cell or parallel cell block thus determined may be determined to be the cell or parallel cell block that should be discharged in the battery pack 41 equipped with a discharging circuit for equalization, by using the discharging circuit.

In the above embodiment, a description is given of a case in which the battery state analysis system 1 is built on an in-house server provided in a data center or an in-house facility or on a cloud server. In this regard, the battery state analysis system 1 may be incorporated in the battery control unit 46 or the vehicle control unit 30. In this case, the wireless communication unit 36 may be omitted.

In the above embodiment, a four-wheeled electric-powered vehicle is assumed as the electric-powered vehicle 3. The electric-powered vehicle 3 may be an electric motorcycle (electric scooter) or an electric bicycle. Further, electric-powered vehicles include not only full-spec electric-powered vehicles but also low-speed electric-powered vehicles such as golf carts and land cars used in shopping malls, entertainment facilities, etc. The battery state analysis system 1 according to the present disclosure can also be applied to state analysis of battery packs 41 mounted on electric ships, multicopters (drones), stationary electricity storage systems, information equipment (e.g., notebook PCs, tablets, smartphones) and the like.

The embodiment may be defined by the following items.

### Item 1

A battery state analysis system (1) including:
a data acquisition unit (111) that acquires, in a battery pack (41) including a plurality of cells (E1-En) connected in series or a battery pack (41) including parallel cell blocks connected in series, the parallel cell block being comprised of a plurality of cells (E1-En) connected in parallel, an ID of a cell or a parallel cell block presenting a maximum voltage value at each sampling and a voltage and/or an ID of a cell or a parallel cell block presenting a minimum voltage value at each sampling and a voltage value for a predetermined period;
a data processing unit (112) that, for each ID, i) calculates a difference between the voltage value and a representative voltage value that occurs when the maximum voltage value is presented and calculates a statistical value of the difference on a maximum voltage side in the predetermined period and/or ii) calculates a difference between the voltage value and the representative value that occurs when the minimum voltage is presented and calculates a statistical value of the difference on a minimum voltage side in the predetermined period; and
a determination unit (113) that i) determines a cell or a parallel cell block of an ID in which the statistical value on the maximum voltage side deviates from an allowable range on a high voltage side as a recommended target for equalization discharge and/or ii) determines a cell or a parallel cell block of an ID in which the statistical value on the minimum voltage side deviates from an allowable range on a low voltage side as a recommended target for equalization charge.

According to this embodiment, it is possible to properly determine a cell or a parallel cell block that should be subject to equalization discharge and/or equalization charge.

### Item 2

The battery state analysis system (1) according to Item 1,
wherein the data processing unit (112)
calculates the statistical value on the maximum voltage side for the ID of a predetermined number of cells or parallel cell blocks ranked highest in a frequency of presenting the maximum voltage value in the predetermined period, and
calculates the statistical value on the minimum voltage side for the ID of a predetermined number of cells or parallel cell blocks ranked highest in a frequency of presenting the minimum voltage value in the predetermined period.

According to this embodiment, the amount of calculation can be reduced.

### Item 3

The battery state analysis system (1) according to Item 1 or 2,
wherein the data processing unit (112)
calculates a maximum voltage average value by averaging maximum voltage values sampled in the predetermined period and a minimum voltage average value by averaging minimum voltage values sampled in the predetermined period and calculates an average differential voltage value by subtracting the minimum voltage average value from the maximum voltage average value,
calculates a cumulative average differential voltage value by adding up the average differential voltage value each time the average differential voltage value in the predetermined period is calculated, and
when a currently calculated average differential voltage value in the predetermined period is smaller by a first preset value or more than a previously calculated average differential voltage in the predetermined period, outputs a notification.

According to this embodiment, it is possible to notify a user of an improvement in the battery state.

### Item 4

The battery state analysis system (1) according to Item 1 or 2,
wherein the data processing unit (112)
calculates a maximum voltage average value by averaging maximum voltage values sampled in the predetermined period and a minimum voltage average value by averaging minimum voltage values sampled in the predetermined period and calculates an average differential voltage value by subtracting the minimum voltage average value from the maximum voltage average value,
calculates a cumulative average differential voltage value by adding up the average differential voltage value each time the average differential voltage value in the predetermined period is calculated, and
when a currently calculated average differential voltage value in the predetermined period is smaller by a first preset value or more than a previously calculated average differential voltage in the predetermined period, resets the cumulative average differential voltage value and then adds the currently calculated average differential voltage value in the predetermined period.

According to this embodiment, it is possible to properly determine the necessity of an equalization process.

### Item 5

The battery state analysis system (1) according to Item 4,
wherein, when the currently calculated average difference voltage in the predetermined period is smaller than a first threshold value or when the currently calculated average difference voltage in the predetermined period is smaller than the first threshold value and the cumulative average differential voltage value is smaller than a second threshold value, the data processing unit (112) skips a process of calculating the statistical value on the maximum voltage side and the statistical value on the minimum voltage side in the current predetermined period.

According to this embodiment, the amount of calculation can be reduced.

### Item 6

The battery state analysis system (1) according to Item 1 or 2,
wherein the data acquisition unit (111) acquires an SOC (State Of Charge) of the battery pack (41) at each sampling for a predetermined period, and
wherein the data processing unit (112) excludes from data processing voltage values sampled when the SOC of the battery pack (41) is smaller than a second preset value.

According to this embodiment, it is possible to improve accuracy of determination.

### Item 7

The battery state analysis system (1) according to Item 1 or 2,
wherein the data acquisition unit (111) acquires an SOC (State Of Charge) of the battery pack (41) at each sampling for a predetermined period, and
wherein the data processing unit (112) excludes from data processing voltage values sampled when the SOC of the battery pack (41) is equal to or larger than a third preset value.

According to this embodiment, it is possible to improve accuracy of determination.

### Item 8

The battery state analysis system (1) according to Item 1 or 2,
wherein the data acquisition unit (111) acquires a current value of the battery pack (41) at each sampling for a predetermined period, and
wherein the data processing unit (112) excludes from data processing voltage values sampled when the current value of the battery pack (41) is equal to or larger than a fourth preset value or smaller than a fifth preset value.

According to this embodiment, it is possible to improve accuracy of determination.

### Item 9

The battery state analysis system (1) according to Item 1 or 2,
wherein the data acquisition unit (111) acquires an SOC (State Of Charge) of the battery pack (41) at each sampling for a predetermined period, and
wherein the data processing unit (112) calculates the statistical value on the maximum voltage side and the statistical value on the minimum voltage side for each SOC class derived from dividing the SOC at predetermined intervals,
wherein the determination unit (113)
determines, as a recommended target for equalization discharge, a cell or a parallel cell block of an ID in which the statistical value on the maximum voltage side deviates from the allowable range on the high voltage side in a predetermined number of SOC classes or more, and
determines, as a recommended target for equalization charge, a cell or a parallel cell block of an ID in which the statistical value on the minimum voltage side deviates from the allowable range on the low voltage side in a predetermined number of SOC classes or more.

According to this embodiment, it is possible to improve accuracy of determination.

### Item 10

A battery state analysis method including:
acquiring, in a battery pack (41) including a plurality of cells (E1-En) connected in series or a battery pack (41) including parallel cell blocks connected in series, the parallel cell block being comprised of a plurality of cells (E1-En) connected in parallel, an ID of a cell or a parallel cell block presenting a maximum voltage value at each sampling and a voltage and/or an ID of a cell or a parallel cell block presenting a minimum voltage value at each sampling and a voltage value for a predetermined period;
for each ID, i) calculating a difference between the voltage value and a representative voltage value that occurs when the maximum voltage value is presented and calculates a statistical value of the difference on a maximum voltage side in the predetermined period and/or ii) calculating a difference between the voltage value and the representative value that occurs when the minimum voltage is presented and calculates a statistical value of the difference on a minimum voltage side in the predetermined period; and
i) determining a cell or a parallel cell block of an ID in which the statistical value on the maximum voltage side deviates from an allowable range on a high voltage side as a recommended target for equalization discharge and/or ii) determining a cell or a parallel cell block of an ID in which the statistical value on the minimum voltage side deviates from an allowable range on a low voltage side as a recommended target for equalization charge.

According to this embodiment, it is possible to properly determine a cell or a parallel cell block that should be subject to equalization discharge and/or equalization charge.

### Item 11

A battery state analysis program including computer-implemented modules including:
a module that acquires, in a battery pack (41) including a plurality of cells (E1-En) connected in series or a battery pack (41) including parallel cell blocks connected in series, the parallel cell block being comprised of a plurality of cells (E1-En) connected in parallel, an ID of a cell or a parallel cell block presenting a maximum voltage value at each sampling and a voltage and/or an ID of a cell or a parallel cell block presenting a minimum voltage value at each sampling and a voltage value for a predetermined period;
a module that, for each ID, i) calculates a difference between the voltage value and a representative voltage value that occurs when the maximum voltage value is presented and calculates a statistical value of the difference on a maximum voltage side in the predetermined period and/or ii) calculates a difference between the voltage value and the representative value that occurs when the minimum voltage is presented and calculates a statistical value of the difference on a minimum voltage side in the predetermined period; and
a module that i) determines a cell or a parallel cell block of an ID in which the statistical value on the maximum voltage side deviates from an allowable range on a high voltage side as a recommended target for equalization discharge and/or ii) determines a cell or a parallel cell block of an ID in which the statistical value on the minimum voltage side deviates from an allowable range on a low voltage side as a recommended target for equalization charge.

According to this embodiment, it is possible to properly determine a cell or a parallel cell block that should be subject to equalization discharge and/or equalization charge.

1. A battery state analysis system comprising:
a data acquisition unit that acquires, in a battery pack including a plurality of cells connected in series or a battery pack including parallel cell blocks connected in series, the parallel cell block being comprised of a plurality of cells connected in parallel, an ID of a cell or a parallel cell block presenting a maximum voltage value at each sampling and a voltage and/or an ID of a cell or a parallel cell block presenting a minimum voltage value at each sampling and a voltage value for a predetermined period;
a data processing unit that, for each ID, i) calculates a difference between the voltage value and a representative voltage value that occurs when the maximum voltage value is presented and calculates a statistical value of the difference on a maximum voltage side in the predetermined period and/or ii) calculates a difference between the voltage value and the representative value that occurs when the minimum voltage is presented and calculates a statistical value of the difference on a minimum voltage side in the predetermined period; and
a determination unit that i) determines a cell or a parallel cell block of an ID in which the statistical value on the maximum voltage side deviates from an allowable range on a high voltage side as a recommended target for equalization discharge and/or ii) determines a cell or a parallel cell block of an ID in which the statistical value on the minimum voltage side deviates from an allowable range on a low voltage side as a recommended target for equalization charge.

2. The battery state analysis system according to claim 1,
wherein the data processing unit
calculates the statistical value on the maximum voltage side for the ID of a predetermined number of cells or parallel cell blocks ranked highest in a frequency of presenting the maximum voltage value in the predetermined period, and
calculates the statistical value on the minimum voltage side for the ID of a predetermined number of cells or parallel cell blocks ranked highest in a frequency of presenting the minimum voltage value in the predetermined period.

3. The battery state analysis system according to claim 1,
wherein the data processing unit
calculates a maximum voltage average value by averaging maximum voltage values sampled in the predetermined period and a minimum voltage average value by averaging minimum voltage values sampled in the predetermined period and calculates an average differential voltage value by subtracting the minimum voltage average value from the maximum voltage average value,
calculates a cumulative average differential voltage value by adding up the average differential voltage value each time the average differential voltage value in the predetermined period is calculated, and
when a currently calculated average differential voltage value in the predetermined period is smaller by a first preset value or more than a previously calculated average differential voltage in the predetermined period, outputs a notification.

4. The battery state analysis system according to claim 1,
wherein the data processing unit
calculates a maximum voltage average value by averaging maximum voltage values sampled in the predetermined period and a minimum voltage average value by averaging minimum voltage values sampled in the predetermined period and calculates an average differential voltage value by subtracting the minimum voltage average value from the maximum voltage average value,
calculates a cumulative average differential voltage value by adding up the average differential voltage value each time the average differential voltage value in the predetermined period is calculated, and
when a currently calculated average differential voltage value in the predetermined period is smaller by a first preset value or more than a previously calculated average differential voltage in the predetermined period, resets the cumulative average differential voltage value and then adds the currently calculated average differential voltage value in the predetermined period.

5. The battery state analysis system according to claim 4,
wherein, when the currently calculated average difference voltage in the predetermined period is smaller than a first threshold value or when the currently calculated average difference voltage in the predetermined period is smaller than the first threshold value and the cumulative average differential voltage value is smaller than a second threshold value, the data processing unit skips a process of calculating the statistical value on the maximum voltage side and the statistical value on the minimum voltage side in the current predetermined period.

6. The battery state analysis system according to claim 1,
wherein the data acquisition unit acquires an SOC (State Of Charge) of the battery pack at each sampling for a predetermined period, and
wherein the data processing unit excludes from data processing voltage values sampled when the SOC of the battery pack is smaller than a second preset value.

7. The battery state analysis system according to claim 1,
wherein the data acquisition unit acquires an SOC (State Of Charge) of the battery pack at each sampling for a predetermined period, and
wherein the data processing unit excludes from data processing voltage values sampled when the SOC of the battery pack is equal to or larger than a third preset value.

8. The battery state analysis system according to claim 1,
wherein the data acquisition unit acquires a current value of the battery pack at each sampling for a predetermined period, and
wherein the data processing unit excludes from data processing voltage values sampled when the current value of the battery pack is equal to or larger than a fourth preset value or smaller than a fifth preset value.

9. The battery state analysis system according to claim 1,
wherein the data acquisition unit acquires an SOC (State Of Charge) of the battery pack at each sampling for a predetermined period, and
wherein the data processing unit calculates the statistical value on the maximum voltage side and the statistical value on the minimum voltage side for each SOC class derived from dividing the SOC at predetermined intervals,
wherein the determination unit
determines, as a recommended target for equalization discharge, a cell or a parallel cell block of an ID in which the statistical value on the maximum voltage side deviates from the allowable range on the high voltage side in a predetermined number of SOC classes or more, and
determines, as a recommended target for equalization charge, a cell or a parallel cell block of an ID in which the statistical value on the minimum voltage side deviates from the allowable range on the low voltage side in a predetermined number of SOC classes or more.

10. A battery state analysis method including:
acquiring, in a battery pack including a plurality of cells connected in series or a battery pack including parallel cell blocks connected in series, the parallel cell block being comprised of a plurality of cells connected in parallel, an ID of a cell or a parallel cell block presenting a maximum voltage value at each sampling and a voltage and/or an ID of a cell or a parallel cell block presenting a minimum voltage value at each sampling and a voltage value for a predetermined period;
for each ID, i) calculating a difference between the voltage value and a representative voltage value that occurs when the maximum voltage value is presented and calculates a statistical value of the difference on a maximum voltage side in the predetermined period and/or ii) calculating a difference between the voltage value and the representative value that occurs when the minimum voltage is presented and calculates a statistical value of the difference on a minimum voltage side in the predetermined period; and
i) determining a cell or a parallel cell block of an ID in which the statistical value on the maximum voltage side deviates from an allowable range on a high voltage side as a recommended target for equalization discharge and/or ii) determining a cell or a parallel cell block of an ID in which the statistical value on the minimum voltage side deviates from an allowable range on a low voltage side as a recommended target for equalization charge.

11. A non-transitory computer-readable recording medium having embodied thereon a battery state analysis program comprising computer-implemented modules including:
a module that acquires, in a battery pack including a plurality of cells connected in series or a battery pack including parallel cell blocks connected in series, the parallel cell block being comprised of a plurality of cells connected in parallel, an ID of a cell or a parallel cell block presenting a maximum voltage value at each sampling and a voltage and/or an ID of a cell or a parallel cell block presenting a minimum voltage value at each sampling and a voltage value for a predetermined period;
a module that, for each ID, i) calculates a difference between the voltage value and a representative voltage value that occurs when the maximum voltage value is presented and calculates a statistical value of the difference on a maximum voltage side in the predetermined period and/or ii) calculates a difference between the voltage value and the representative value that occurs when the minimum voltage is presented and calculates a statistical value of the difference on a minimum voltage side in the predetermined period; and
a module that i) determines a cell or a parallel cell block of an ID in which the statistical value on the maximum voltage side deviates from an allowable range on a high voltage side as a recommended target for equalization discharge and/or ii) determines a cell or a parallel cell block of an ID in which the statistical value on the minimum voltage side deviates from an allowable range on a low voltage side as a recommended target for equalization charge.
